(19) United States
(12) Patent Application Publication
(10) Pub. No.: US 2026/0247801 A1
(43) Pub. Date: Aug. 20, 2026

(54) DISPLAY DEVICE AND ELECTRONIC DEVICE

(71) Applicant: Samsung Display Co., Ltd., Yongin-si (KR)

(72) Inventors: Seo Young LIM, Yongin-si (KR); Kwang Soo BAE, Yongin-si (KR); Soo Yeong HONG, Yongin-si (KR); Hyang A PARK, Yongin-si (KR); Go Een JEONG, Yongin-si (KR)

(21) Appl. No.: 19/415,227

(22) Filed: Dec. 10, 2025

(30) Foreign Application Priority Data
Feb. 14, 2025 (KR) 10-2025-0019241

(51) Int. Cl. H10K 59/122; H10K 59/131; H10K 59/60; H10K 59/80

(52) U.S. Cl. CPC H10K 59/122; H10K 59/131; H10K 59/60; H10K 59/80516

(57) ABSTRACT

A display device includes: a substrate; a transistor layer on the substrate; and an optical element layer on the transistor layer, wherein the optical element layer includes: a pixel electrode on the transistor layer; a bank on the pixel electrode and having a first through hole overlapping a portion of the pixel electrode; a photovoltaic layer on the pixel electrode; an intermediate electrode on the photovoltaic layer; a light emitting layer on the intermediate electrode; and a common electrode on the light emitting layer.

### CROSS-REFERENCE TO RELATED APPLICATION

The present application claims priority to and the benefit of Korean Patent Application No. 10-2025-0019241, filed on Feb. 14, 2025, in the Korean Intellectual Property Office, the entire disclosure of which is incorporated herein by reference.

### BACKGROUND

### 1. Field

Aspects of some embodiments of the present disclosure relate to a display device and an electronic device.

### 2. Description of the Related Art

An organic light emitting display apparatus includes display elements whose luminance may be changed by a current, such as organic light emitting diodes.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device, and for example, to a display device and electronic device whose resolutions and retention times of batteries may be relatively improved.

Aspects of the present disclosure provide a display device and electronic device whose resolutions and retention times of batteries may be relatively improved.

According to an aspect of the present disclosure, a display device includes: a substrate; a transistor layer on the substrate; and an optical element layer on the transistor layer, wherein the optical element layer includes: a pixel electrode on the transistor layer; a bank on the pixel electrode and having a first through hole overlapping a portion of the pixel electrode; a photovoltaic layer on the pixel electrode; an intermediate electrode on the photovoltaic layer; a light emitting layer on the intermediate electrode; and a common electrode on the light emitting layer.

According to another aspect of the present disclosure, an optical device includes a display device providing a display screen, wherein the display device includes: a substrate; a transistor layer on the substrate; and an optical element layer on the transistor layer, and the optical element layer includes: a pixel electrode on the transistor layer; a bank on the pixel electrode and having a first through hole overlapping a portion of the pixel electrode; a photovoltaic layer on the pixel electrode; an intermediate electrode on the photovoltaic layer; a light emitting layer on the intermediate electrode; and a common electrode on the light emitting layer.

According to some embodiments, resolutions and retention times of batteries of a display device and an electronic device may be relatively improved.

For example, according to some embodiments, a light emitting element and a photovoltaic element are in a vertical direction so as to overlap each other, and thus, an area of a pixel in a horizontal direction may be relatively reduced. Accordingly, the number of pixels per unit area of a display area may be increased. Accordingly, a resolution of the display device may be relatively improved.

In addition, according to some embodiments, electric energy may be generated from the photovoltaic element through external light and light from the light emitting element. Accordingly, a retention time of a battery and a driving time and power consumption of the display device may be relatively improved.

The characteristics of embodiments according to the present disclosure are not limited to the above-described characteristics and other characteristics which are not described herein will become more apparent to those skilled in the art from the following description.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a cross-sectional view illustrating the display device according to some embodiments;

FIG. 3 is a plan view illustrating a display unit of the display device according to some embodiments;

FIG. 4 is a block diagram illustrating a display panel and a display driver according to some embodiments;

FIG. 5 is a circuit diagram of one pixel of the display device according to some embodiments;

FIG. 6 is a schematic view of the display device according to some embodiments;

FIG. 7 is a detailed cross-sectional view of the display device according to some embodiments;

FIGS. 8 and 9 are views for describing a charging operation of the display device of FIG. 6;

FIG. 10 is a schematic view of a display device according to some embodiments;

FIG. 11 is a detailed cross-sectional view of the display device according to some embodiments;

FIGS. 12 and 13 are views for describing a charging operation of the display device of FIG. 10;

FIG. 14 is a block diagram of an electronic device according to some embodiments; and

FIGS. 15 to 17 are schematic views of electronic devices according to some embodiments.

### DETAILED DESCRIPTION

Aspects of some embodiments according to the present disclosure will now be described more fully hereinafter with reference to the accompanying drawings, in which aspects of some embodiments according to the present disclosure are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments according to the present disclosure will be described with reference to the accompanying drawings.

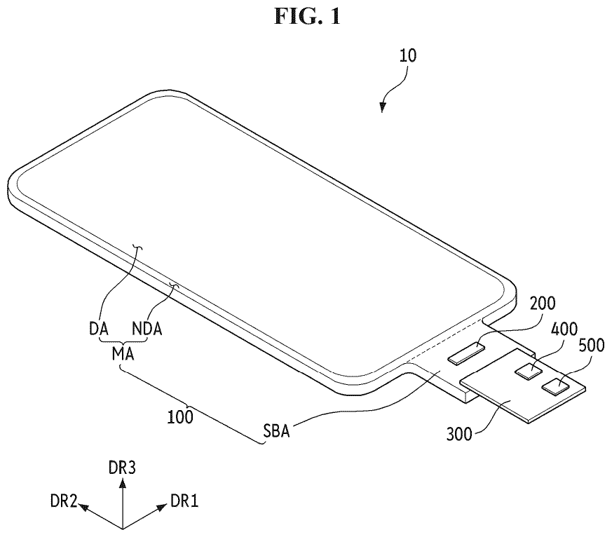

FIG. 1 is a perspective view illustrating a display device according to some embodiments.

Referring to FIG. 1, a display device 10 may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). As an example, the display device 10 may be applied as a display unit of televisions, laptop computers, monitors, billboards, or the Internet of Things (IOTs). As another example, the display device 10 may be applied to wearable devices such as smart watches, watch phones, glasses-type displays, and head mounted displays (HMDs).

The display device 10 may have a shape similar to a rectangular shape in a plan view. For example, the display device 10 may have a shape similar to a rectangular shape, in a plan view, having short sides in a first direction DR1 and long sides in a second direction DR2. A corner where the short side in the first direction DR1 and the long side in the second direction DR2 meet may be rounded with a selected curvature or right-angled. The shape of the display device 10 in a plan view is not limited to the rectangular shape, and may be a shape similar to other polygonal shapes, a circular shape, an elliptical shape, or an irregular shape.

The display device 10 may include a display panel 100, a display driver 200, a circuit board 300, a touch driver 400, and a power supply unit 500.

The display panel 100 may include a main area MA and a sub-area SBA.

The main area MA may include a display area DA including pixels displaying images and a non-display area NDA arranged around (e.g., in a periphery or outside a footprint of) the display area DA where images are not displayed. The display area DA may emit light from a plurality of emission areas or a plurality of opening areas. For example, the display panel 100 may include pixel circuits including switching elements, a bank defining the emission areas and the opening areas, and self-light emitting elements.

For example, the self-light emitting element ED may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto.

The non-display area NDA may be an area outside (e.g., surrounding, in a periphery, and/or outside a footprint of) the display area DA. The non-display area NDA may be defined as an edge area of the main area MA of the display panel 100. The non-display area NDA may include a gate driver supplying gate signals to gate lines and fan-out lines connecting the display driver 200 and the display area DA to each other.

The sub-area SBA may extend from one side of the main area MA. The sub-area SBA may include a flexible material that may be bent, folded, and rolled without damaging the display panel 100 or the display device 10. For example, when the sub-area SBA is bent, the sub-area SBA may overlap the main area MA in a thickness direction (e.g., a third direction DR3). The sub-area SBA may include the display driver 200 and pad portions connected to the circuit board 300. Alternatively, the sub-area SBA may be omitted, and the display driver 200 and the pad portions may be located in the non-display area NDA.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be located in the sub-area SBA, and may overlap the main area MA in the thickness direction (third direction DR3) by bending of the sub-area SBA. As another example, the display driver 200 may be mounted on the circuit board 300.

The circuit board 300 may be attached onto the pad portions of the display panel 100 using an anisotropic conductive film (ACF). Lead lines of the circuit board 300 may be electrically connected to the pad portions of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply touch driving signals to a plurality of touch electrodes of the touch sensing unit and sense change amounts in capacitance between the plurality of touch electrodes. For example, the touch driving signal may be a pulse signal having a selected frequency. The touch driver 400 may decide whether or not an input has occurred and calculate input coordinates, based on the change amounts in capacitance between the plurality of touch electrodes. The touch driver 400 may be formed as an integrated circuit (IC).

The power supply unit 500 may be located on the circuit board 300 and may supply source voltages to the display driver 200 and the display panel 100. The power supply unit 500 may generate a driving voltage and supply the driving voltage to a driving voltage line VDL, may generate an initialization voltage and supply the initialization voltage to an initialization voltage line VIL, may generate a reference voltage and supply the reference voltage to a reference voltage line VRL, and may generate a common voltage and supply the common voltage to a common voltage line. In this case, the common voltage of the common voltage line may be supplied to a common electrode common to light emitting elements ED of a plurality of pixels. The driving voltage may be a high potential voltage for driving the light emitting element ED, and the common voltage may be a low potential voltage for driving the light emitting element ED.

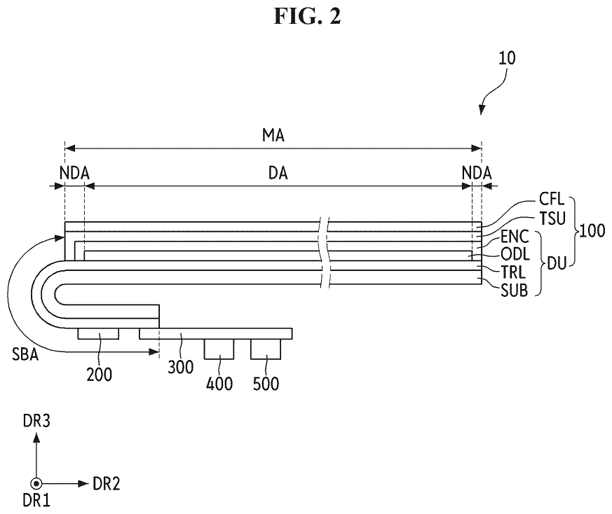

FIG. 2 is a cross-sectional view illustrating further details of the display device according to some embodiments.

Referring to FIG. 2, the display panel 100 may include a display unit DU, a touch sensing unit TSU, and a color filter layer CFL. The display unit DU may include a substrate SUB, a transistor layer TRL, an optical element layer ODL, and an encapsulation layer ENC.

The substrate SUB may be a base substrate or a base member. The substrate SUB may be a flexible substrate that may be bent, folded, and rolled. As an example, the substrate SUB may include a polymer resin such as polyimide (PI), but embodiments according to the present disclosure are not limited thereto. As another example, the substrate SUB may include a glass material or a metal material.

The transistor layer TRL may be located on the substrate SUB. The transistor layer TRL may include a plurality of transistors and a capacitor that constitute pixel circuits of pixels PX. The transistor layer TRL may further include gate lines, data lines, power lines, gate control lines, fan-out lines connecting the display driver 200 and the data lines to each other, and lead lines connecting the display driver 200 and the pad portions to each other. Each of the thin film transistors may include a semiconductor region, a source electrode, a drain electrode, and a gate electrode. For example, when a gate driver is formed on one side of the non-display area NDA of the display panel 100, the gate driver may include thin film transistors.

The transistor layer TRL may be located in the display area DA, the non-display area NDA, and the sub-area SBA. The transistors of each of the pixels, the gate lines, the data lines, and the power lines of the transistor layer TRL may be located in the display area DA. The gate control lines and the fan-out lines of the transistor layer TRL may be located in the non-display area NDA. The lead lines of the transistor layer TRL may be located in the sub-area SBA.

The optical element layer ODL may be located on the transistor layer TRL. The optical element layer ODL may include a plurality of optical elements OD in which a pixel electrode, a photovoltaic layer, an intermediate electrode, a light emitting layer, and a common electrode are sequentially stacked to emit light and generate electric energy and a bank. The plurality of optical elements OD of the optical element layer ODL may be located in the display area DA. Here, the pixel electrode of the optical element OD may be an anode electrode of the optical element OD, and the common electrode of the optical element OD may be a cathode electrode of the optical element OD.

The photovoltaic layer may convert light energy into electric energy. The photovoltaic layer may include a battery material receiving light and generating electric energy.

The light emitting layer may be an organic light emitting layer including an organic material. The light emitting layer may include a hole transporting layer, an organic light emitting layer, and an electron transporting layer. When the pixel electrode receives a selected voltage through the thin film transistor of the transistor layer TRL and the common electrode receives a cathode voltage, holes and electrons may move to the organic light emitting layer through the hole transporting layer and the electron transporting layer, respectively, and may be combined with each other in the organic light emitting layer to emit light. For example, the pixel electrode may be an anode electrode and the common electrode may be a cathode electrode, but embodiments according to the present disclosure are not limited thereto.

The encapsulation layer ENC may cover an upper surface and side surfaces of the optical element layer ODL, and may protect the optical element layer ODL. The encapsulation layer ENC may include at least one inorganic film and at least one organic film for encapsulating the optical element layer ODL.

The touch sensing unit TSU may be located on the encapsulation layer ENC. The touch sensing unit TSU may include a plurality of touch electrodes for sensing a user's touch in a capacitance manner and touch lines connecting the plurality of touch electrodes and the touch driver 400 to each other. For example, the touch sensing unit TSU may sense the user's touch in a mutual capacitance manner or a self-capacitance manner.

As another example, the touch sensing unit TSU may be located on a separate substrate located on the display unit DU. In this case, the substrate supporting the touch sensing unit TSU may be a base member encapsulating the display unit DU.

The plurality of touch electrodes of the touch sensing unit TSU may be located in a touch sensor area overlapping the display area DA. The touch lines of the touch sensing unit TSU may be located in a touch peripheral area overlapping the non-display area NDA.

The color filter layer CFL may be located on the touch sensing unit TSU. The color filter layer CFL may include a plurality of color filters respectively corresponding to the plurality of emission areas. Each of the color filters may selectively transmit light of a specific wavelength and block or absorb light of other wavelengths. The color filter layer CFL may absorb some of light introduced from the outside of the display device 10 to relatively reduce reflected light by external light. Accordingly, the color filter layer CFL may prevent or reduce distortion of colors due to external light reflection.

Because the color filter layer CFL is directly located on the touch sensing unit TSU, the display device 10 may not require a separate substrate for the color filter layer CFL. Accordingly, a thickness of the display device 10 may be relatively reduced.

The sub-area SBA of the display panel 100 may extend from one side of the main area MA. The sub-area SBA may include a flexible material that may be bent, folded, and rolled. For example, when the sub-area SBA is bent, the sub-area SBA may overlap the main area MA in the thickness direction (third direction DR3). The sub-area SBA may include the display driver 200 and the pad portions connected to the circuit board 300.

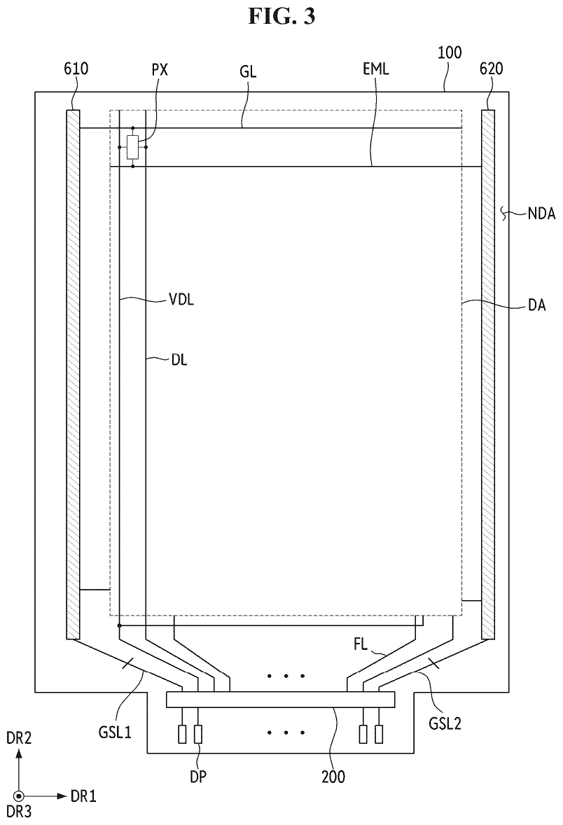

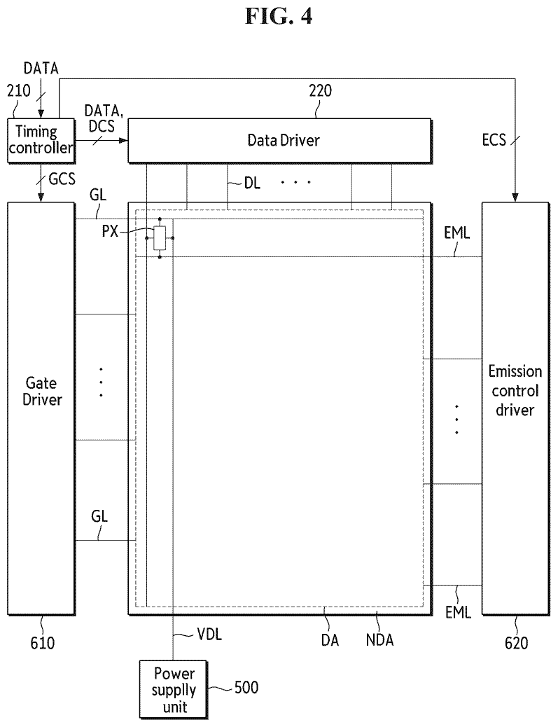

FIG. 3 is a plan view illustrating a display unit of the display device according to some embodiments, and FIG. 4 is a block diagram illustrating a display panel and a display driver according to some embodiments.

Referring to FIGS. 3 and 4, the display panel 100 may include a display area DA and a non-display area NDA.

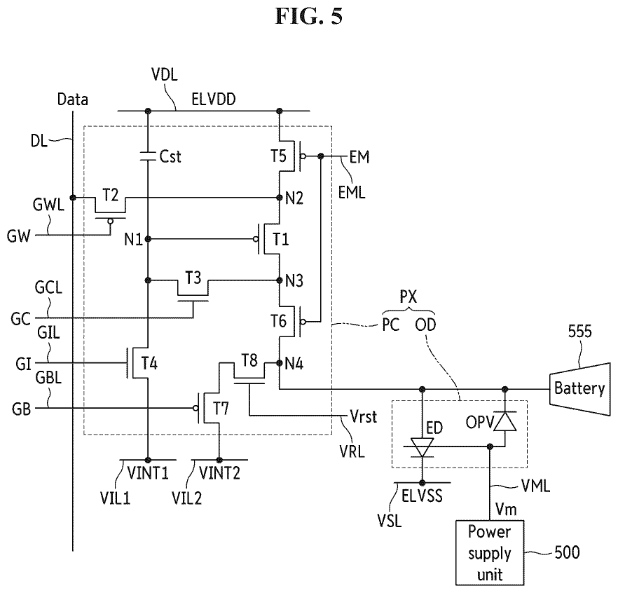

The display area DA may include a plurality of pixels PX, and a plurality of driving voltage lines VDL, a plurality of common voltage lines VSL (see FIG. 5), a plurality of gate lines GL, a plurality of emission lines EML, and a plurality of data lines DL that are connected to the plurality of pixels PX. Although FIGS. 3 and 4 illustrate a single pixel PX, a single driving voltage line VDL, a single common voltage line VSL, a single gate line GL, a single emission line EML, and a single data line DL for ease of illustration, as person having ordinary skill in the art would appreciate, the display panel 100 may include any suitable number of the above elements according to the design and size of the display panel 100.

Each of the plurality of pixels PX may be connected to the gate line GL, the data line DL, the emission line EML, the driving voltage line VDL, and the common voltage line VSL. Each of the plurality of pixels PX may include at least one transistor, a light emitting element ED, and a capacitor.

The gate lines GL may extend in the first direction DR1, and may be spaced apart from each other in the second direction DR2 crossing the first direction DR1. The gate lines GL may be arranged along the second direction DR2. The gate lines GL may sequentially supply gate signals to the plurality of pixels PX.

The emission lines EML may extend in the first direction DR1, and may be spaced apart from each other in the second direction DR2. The emission lines EML may be arranged along the second direction DR2. The emission lines EML may sequentially supply emission signals to the plurality of pixels PX.

The data lines DL may extend in the second direction DR2, and may be spaced apart from each other in the first direction DR1. The data lines DTL may be arranged along the first direction DR1. The data lines DL may supply data voltages to the plurality of pixels PX. The data voltage may determine luminance of each of the plurality of pixels PX.

The driving voltage lines VDL may extend in the second direction DR2, and may be spaced apart from each other in the first direction DR1. The driving voltage lines VDL may be arranged along the first direction DR1. The driving voltage lines VDL may supply a first driving voltage to the plurality of pixels PX. The first driving voltage may be a high potential voltage for driving the light emitting elements ED of the pixels PX.

The non-display areas NDA may surround (e.g., entirely surround, in a periphery, and/or outside a footprint of) the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltages received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-area SBA may extend from one side of the non-display area NDA. The sub-area SBA may include the display driver 200 and pad portions DP. The pad portion DP may be located more adjacent to an edge of one side of the sub-area SBA than the display driver 200 is. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may control an operation timing of the data driver 220 by generating a data control signal DCS based on the timing signals, may control an operation timing of the gate driver 610 by generating the gate control signal GCS based on the timing signals, and may control an operation timing of the emission control driver 620 by generating the emission control signal ECS based on the timing signals. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. Gate signals of the gate driver 610 may select pixels PX to which the data voltages are supplied, and the selected pixels PX may receive the data voltages through the data lines DL.

The power supply unit 500 may be located on the circuit board 300 and may supply source voltages to the display driver 200 and the display panel 100. The power supply unit 500 may generate a driving voltage and supply the driving voltage to the driving voltage line VDL, may generate an initialization voltage and supply the initialization voltage to the initialization voltage line VIL, and may generate a common voltage and supply the common voltage to the common electrode common to the light emitting elements ED of the plurality of pixels.

The gate driver 610 may be located outside one side of the display area DA or on one side of the non-display area NDA, and the emission control driver 620 may be located outside the other side of the display area DA or on the other side of the non-display area NDA, but embodiments according to the present disclosure are not limited thereto. As another example, the gate driver 610 and the emission control driver 620 may be located on any one of one side and the other side of the non-display area NDA.

The gate driver 610 may include a plurality of transistors generating gate signals based on the gate control signal GCS. The emission control driver 620 may include a plurality of transistors generating emission signals based on the emission control signal ECS. For example, the transistors of the gate driver 610 and the transistors of the emission control driver 620 may be formed at a same layer as the transistors of each of the pixels PX. The gate driver 610 may supply the gate signals to the gate lines GL, and the emission control driver 620 may supply the emission signals to the emission lines EML.

FIG. 5 is a circuit diagram of one pixel of the display device according to some embodiments. Although FIG. 5 illustrates various components in a pixel according to some embodiments, embodiments according to the present disclosure are not limited thereto, and according to various embodiments, the pixel may include additional components, or fewer components, without departing from the spirit and scope of embodiments according to the present disclosure.

Referring to FIG. 5, the pixel PX may be connected to a first gate line GWL, a second gate line GCL, a third gate line GIL, a fourth gate line GBL, an emission line EML, a data line DL, a driving voltage line VDL, a common voltage line VSL, a first initialization voltage line VIL1, a second initialization voltage line VIL2, and a reset voltage line VRL.

The pixel PX may include a pixel circuit PC and an optical element OD connected to the pixel circuit PC.

The pixel circuit PC may include a first transistor T1, a second transistor T2, a third transistor T3, a fourth transistor T4, a fifth transistor T5, a sixth transistor T6, a seventh transistor T7, an eighth transistor T8, and a capacitor Cst.

The first transistor T1 may include a gate electrode, a source electrode, and a drain electrode. The first transistor T1 may control a source-drain current (e.g., a driving current) according to a data voltage applied to the gate electrode. The driving current flowing through a channel region of the first transistor T1 may be proportional to the square of a difference between a voltage between the source electrode and the gate electrode (e.g., a gate-source voltage) and a threshold voltage of the first transistor T1. The gate electrode of the first transistor T1 may be electrically connected to a first node N1, the source electrode of the first transistor T1 may be electrically connected to a second node N2, and the drain electrode of the first transistor T1 may be electrically connected to a third node N3.

The second transistor T2 may be controlled by a first gate signal GW, and may be connected between the data line DL and the second node N2. The second transistor T2 may be turned on by the first gate signal GW of the first gate line GWL to electrically connect the data line DL and the second node N2, which is the source electrode of the first transistor T1, to each other. A gate electrode of the second transistor T2 may be electrically connected to the first gate line GWL, a source electrode of the second transistor T2 may be electrically connected to the data line DL, and a drain electrode of the second transistor T2 may be electrically connected to the second node N2.

The third transistor T3 may be controlled by a second gate signal GC, and may be connected between the first node N1 and the third node N3. The third transistor T3 may be turned on by the second gate signal GC of the second gate line GCL to electrically connect the first node N1 and the third node N3 to each other. A gate electrode of the third transistor T3 may be electrically connected to the second gate line GCL, a drain electrode of the third transistor T3 may be electrically connected to the first node N1, and a source electrode of the third transistor T3 may be electrically connected to the third node N3.

The fourth transistor T4 may be controlled by a third gate signal GI, and may be connected between the first node N3 and the first initialization voltage line VIL1. The fourth transistor T4 may be turned on by the third gate signal GI of the third gate line GIL to electrically connect the first node N1 and the first initialization voltage line VIL1 to each other. A gate electrode of the fourth transistor T4 may be electrically connected to the third gate line GIL, a drain electrode of the fourth transistor T4 may be electrically connected to the first node N1, and a source electrode of the fourth transistor T4 may be electrically connected to the first initialization voltage line VIL1. The first initialization voltage line VIL may transmit a first initialization voltage VINT1.

The fifth transistor T5 may be controlled by an emission signal EM, and may be connected between the driving voltage line VDL and the second node N2. The fifth transistor T5 may be turned on by the emission signal EM of the emission line EML to electrically connect the driving voltage line VDL and the second node N2 to each other. A gate electrode of the fifth transistor T5 may be electrically connected to the emission line EML, a source electrode of the fifth transistor T5 may be electrically connected to the driving voltage line VDL, and a drain electrode of the fifth transistor T5 may be electrically connected to the second node N2. The driving voltage line VDL may transmit a driving voltage ELVDD. According to some embodiments, the driving voltage ELVDD may be greater than a common voltage ELVSS.

The sixth transistor T6 may be controlled by the emission signal EM, and may be connected between the third node N3 and a fourth node N4. The sixth transistor T6 may be turned on by the emission signal EM of the emission line EML to electrically connect the third node N3 and the fourth node N4 to each other. A gate electrode of the sixth transistor T6 may be electrically connected to the emission line EML, a source electrode of the sixth transistor T6 may be electrically connected to the third node N3, and a drain electrode of the sixth transistor T6 may be electrically connected to the fourth node N4.

The seventh transistor T7 may be controlled by a fourth gate signal GB, and may be connected between a source electrode of the eighth transistor T8 and the second initialization voltage line VIL2. The seventh transistor T7 may be turned on by the fourth gate signal GB of the fourth gate line GBL to electrically connect the source electrode of the eighth transistor T8 and the second initialization voltage line VIL2 to each other. A gate electrode of the seventh transistor T7 may be electrically connected to the fourth gate line GBL, a source electrode of the seventh transistor T7 may be electrically connected to the source electrode of the eighth transistor T8, and a drain electrode of the seventh transistor T7 may be electrically connected to the second initialization voltage line VIL2.

The eighth transistor T8 may be controlled by a reset voltage Vrst, and may be connected between the source electrode of the seventh transistor T7 and the fourth node N4. The eighth transistor T8 may be turned on by the reset voltage Vrst of the reset voltage line VRL to electrically connect the source electrode of the seventh transistor T7 and the fourth node N4 to each other. A gate electrode of the eighth transistor T8 may be electrically connected to the reset voltage line VRL, a drain electrode of the eighth transistor T8 may be electrically connected to the fourth node N4, and the source electrode of the eighth transistor T8 may be electrically connected to the source electrode of the seventh transistor T7.

The capacitor Cst may be electrically connected between the driving voltage line VDL and the first node N1. For example, one electrode of the capacitor Cst may be electrically connected to the driving voltage line VDL, and the other electrode of the capacitor Cst may be electrically connected to the first node N1.

Each of the first transistor T1, the second transistor T2, the fifth transistor T5, the sixth transistor T6, the seventh transistor T7, and the eighth transistor T8 may include a silicon-based active layer. For example, each of the first transistor T1, the second transistor T2, the fifth transistor T5, the sixth transistor T6, the seventh transistor T7, and the eighth transistor T8 may be a P-type transistor including an active layer made of low temperature polycrystalline silicon (LTPS). The active layer made of the low temperature polycrystalline silicon may have high electron mobility and excellent turn-on characteristics. Accordingly, the display device 10 may stably and efficiently drive the plurality of pixels PX by including the transistors having the excellent turn-on characteristics. Each of the first transistor T1, the second transistor T2, the fifth transistor T5, the sixth transistor T6, the seventh transistor T7, and the eighth transistor T8 may output a current introduced into the source electrode to the drain electrode based on a gate low voltage applied to the gate electrode.

Each of the third transistor T3 and the fourth transistor T4 may be an N-type transistor including an oxide-based active layer. The transistor including the oxide-based active layer may have a coplanar structure in which a gate electrode thereof is located at a top. The transistor including the oxide-based active layer may output a current introduced into a drain electrode to a source electrode based on a gate high voltage applied to the gate electrode.

The optical element OD may include a light emitting element ED and a photovoltaic element OPV.

The light emitting element ED may emit light by receiving the driving current. A light emission amount or luminance of the light emitting element ED may be proportional to a magnitude of the driving current. The light emitting element ED may be an organic light emitting diode including an anode electrode, a cathode electrode, and an organic light emitting layer located between these electrodes (e.g., the anode electrode and the cathode electrode of the light emitting element ED). As another example, the light emitting element ED may be an inorganic light emitting element ED including an anode electrode, a cathode electrode, and an inorganic semiconductor located between these electrodes (e.g., the anode electrode and the cathode electrode of the light emitting element ED). As still another example, the light emitting element ED may be a quantum dot light emitting element ED including an anode electrode, a cathode electrode, and a quantum dot light emitting layer located between these electrodes (e.g., the anode electrode and the cathode electrode of the light emitting element ED). As still another example, the light emitting element ED may be a micro light emitting diode. The anode electrode of the light emitting element ED may be electrically connected to the fourth node N4, and the cathode electrode of the light emitting element ED may be connected to the common voltage line VSL. The cathode electrode of the light emitting element ED may receive the common voltage ELVSS (e.g., a low potential voltage) from the common voltage line VSL.

The photovoltaic element OPV may generate a photoelectric phenomenon by receiving light. Here, the light may be, for example, at least one of sunlight from the outside or light from the light emitting element ED. Light energy may be converted into electric energy by the photovoltaic element OPV, and the converted electric energy may be supplied to at least one of the power supply unit 500 or a battery 555. The photovoltaic element OPV may include an anode electrode, a cathode electrode, and a photovoltaic layer between these electrodes (e.g., the anode electrode and the cathode electrode of the photovoltaic element OPV). The photovoltaic element OPV may be connected between the light emitting element ED and the fourth node N4. For example, the anode electrode of the photovoltaic element OPV may be electrically connected to each of the anode electrode and the cathode electrode of the light emitting element ED between the anode electrode of the light emitting element ED and the cathode electrode of the light emitting element ED, and the cathode electrode of the photovoltaic element OPV may be electrically connected to the fourth node N4. In addition, the anode electrode of the photovoltaic element OPV may be connected to an intermediate voltage line VML. An intermediate voltage Vm may be applied to the intermediate voltage line VML. The intermediate voltage line VML may be connected to, for example, the power supply unit 500. Here, the cathode electrode of the photovoltaic element OPV and the anode electrode of the light emitting element ED may be formed integrally with each other.

The optical element OD including such a light emitting element ED and photovoltaic element OPV may be, for example, an element including three electrodes. In other words, the optical element OD may be an element including a pixel electrode, an intermediate electrode, and a common electrode.

Each of the common voltage ELVSS, the first initialization voltage VINT1, a second initialization voltage VINT2, the intermediate voltage Vm, and the reset voltage Vrst may be a direct current (DC) voltage.

The intermediate voltage Vm may be greater than the common voltage ELVSS. For example, the intermediate voltage Vm may be −1 [V], and the common voltage ELVSS may be −2.5 [V]. The intermediate voltage Vm may be provided from, for example, the power supply unit 500. For example, the power supply unit 500 may provide the intermediate voltage Vm to the optical element OD (e.g., the anode electrode of the photovoltaic element OPV) through the intermediate voltage line VML.

The first initialization voltage VINT1 and the second initialization voltage VINT2 may be the same as each other. Each of the first initialization voltage VINT1 and the second initialization voltage VINT1 may be smaller than or equal to the common voltage ELVSS. Each of the first initialization voltage VINT1 and the second initialization voltage VINT1 may be smaller than the intermediate voltage Vm.

The pixel PX may operate in a light emitting mode that provides light through the light emitting element ED and a charging mode that generates electric energy through the photovoltaic element OPV, and the driving voltage ELVDD in the light emitting mode and the driving voltage ELVDD in the charging mode may be different from each other. For example, the driving voltage ELVDD may have a smaller value in the charging mode than in the light emitting mode. Specifically, the driving voltage in the light emitting mode may be 5 [V], and the driving voltage in the charging mode may be −2 [V].

In the light emitting mode, the pixel PX may perform a light emitting operation. For example, in the light emitting mode, the first to eighth transistors T1 to T8 may operate to generate the driving current, and the driving current may be supplied to the light emitting element ED, such that the light emitting element ED may emit the light. As a specific example, in the light emitting mode, the intermediate voltage Vm may be greater than the common voltage ELVSS and smaller than the driving voltage ELVDD. For example, in the light emitting mode, the driving voltage ELVDD may be 5 [V], the common voltage ELVSS may be −2.5 [V], and the intermediate voltage Vm may be −1 [V]. Accordingly, in the light emitting mode, the light emitting element ED may be forward biased, while the photovoltaic element OPV may be reverse biased. Therefore, when the fifth transistor T5, the first transistor T1, and the sixth transistor T6 are turned on in the light emitting mode to generate the driving current, the driving current may be supplied to the light emitting element ED. In the light emitting mode, the light emitting element ED emits the light, and the photovoltaic element OPV does not operate.

In the charging mode, the pixel PX may perform a light emitting operation and a light receiving operation. For example, in the charging mode, the first to eighth transistors T1 to T8 may operate to generate the driving current, and the driving current may be supplied to the light emitting element ED, such that the light emitting element ED may emit the light, and the photovoltaic element OPV may generate the electric energy. As a specific example, in the charging mode, the driving voltage ELVDD may be greater than the common voltage ELVSS and smaller than the intermediate voltage Vm. For example, in the charging mode, the driving voltage ELVDD may be −2 [V], the common voltage ELVSS may be −2.5 [V], and the intermediate voltage Vm may be −1 [V]. Accordingly, in the charging mode, the light emitting element ED and the photovoltaic element OPV may be forward biased. Therefore, when the fifth transistor T5, the first transistor T1, and the sixth transistor T6 are turned on in the charging mode to generate the driving current, the driving current may be supplied to the light emitting element ED, and light from the light emitting element ED and light from the outside of the display device 10 may be supplied to the photovoltaic element OPV (e.g., an operable photovoltaic element OPV). Accordingly, the photovoltaic element OPV may generate the electric energy. The electric energy generated from the photovoltaic element OPV may be charged in the battery 555.

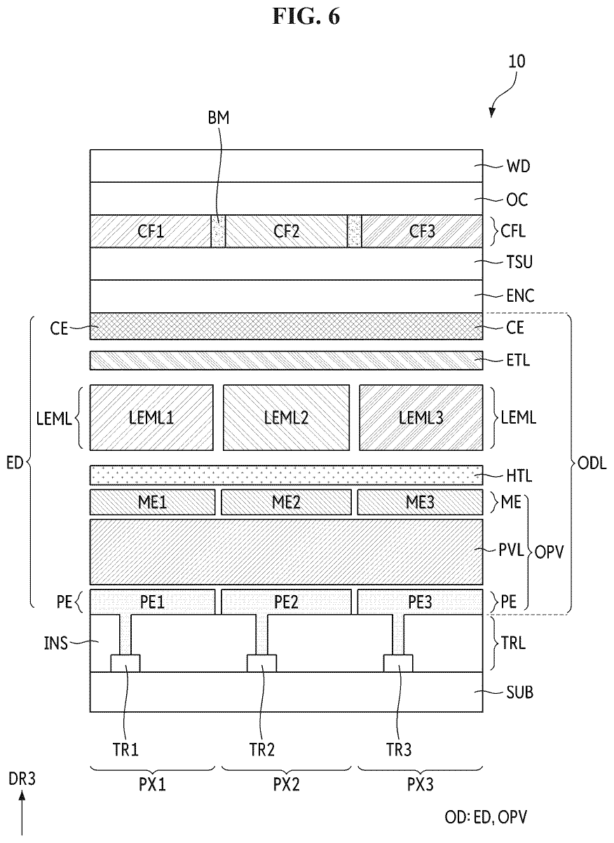

FIG. 6 is a schematic view of the display device 10 according to some embodiments.

The display device 10 according to some embodiments may include a substrate SUB, a transistor layer TRL, an optical element layer ODL, an encapsulation layer ENC, a touch sensing unit TSU, a color filter layer CFL, a light blocking layer BM, an overcoat layer OC, and a window WD, as illustrated in FIG. 6.

The substrate SUB is a base member (or a base layer) of the display panel 100, and may be a rigid substrate SUB or a flexible substrate SUB. According to some embodiments, the substrate SUB may be one of a glass substrate SUB, a quartz substrate SUB, a glass ceramic substrate SUB, a film substrate SUB including a polymer organic material, and a plastic substrate SUB, but embodiments according to the present disclosure are not limited thereto.

The transistor layer TRL may be located on the substrate SUB. For example, the transistor layer TRL may be located between the substrate SUB and a pixel electrode PE. The transistor layer TRL may include a pixel circuit PC. For example, the transistor layer TRL may include pixel transistors TR1, TR2, and TR3 such as the first to eighth transistors T1 to T8 and a capacitor Cst.

As illustrated in FIG. 6, the optical element layer ODL may include an optical element OD. The optical element OD may include a pixel electrode PE, a photovoltaic layer PVL, an intermediate electrode ME, a light emitting layer LEML, and a common electrode CE that are located on the substrate SUB. In addition, the optical element layer ODL may further include a hole transporting layer HTL located between the intermediate electrode ME and the light emitting layer LEML and an electron transporting layer ETL located between the light emitting layer LEML and the common electrode CE. In addition, the optical element layer ODL may further include an electron injecting layer located between the pixel electrode PE and the photovoltaic layer PVL.

The pixel electrode PE may be located on the transistor layer TRL. The pixel electrode PE may be formed as a single layer made of molybdenum (Mo), titanium (Ti), copper (Cu), or aluminum (Al) or formed as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO in order to increase reflectivity. The APC alloy may be an alloy of silver (Ag), palladium (Pd), and copper (Cu).

The photovoltaic layer PVL may be located on the pixel electrode PE. The photovoltaic layer PVL may include a battery material receiving light and converting the light into electric energy For example, the photovoltaic layer PVL may include a crystalline silicon-based (C-SI) material.

The intermediate electrode ME may be located on the photovoltaic layer PVL. The intermediate electrode ME may include a transparent conductive material. For example, the intermediate electrode ME may be made of a material including indium zinc oxide (IZO).

The hole transporting layer HTL may be located on the intermediate electrode ME.

The light emitting layer LEML may be located on the hole transporting layer HTL. The light emitting layer LEML may include an organic material generating light. For example, the light emitting layer LEML may be an organic emitting layer LEML.

The electron transporting layer ETL may be located on the light emitting layer LEML.

The common electrode CE may be located on the electron transporting layer ETL. The common electrode CE may be made of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CE is made of the semi-transmissive conductive material, emission efficiency may be increased by a micro cavity.

The optical element OD may include a light emitting element ED and a photovoltaic element OPV. The pixel electrode PE of the optical element OD may be an anode electrode of the light emitting element ED, and the common electrode CE of the optical element OD may be a cathode electrode of the light emitting element ED. In addition, the intermediate electrode ME of the optical element OD may be an anode electrode of the photovoltaic element OPV, and the pixel electrode PE of the optical element OD may be a cathode electrode of the photovoltaic element OPV.

The encapsulation layer ENC may be located on the optical element layer ODL.

The color filter layer CFL may be located on the encapsulation layer ENC. The light blocking layer BM may be located between color filters CF1, CF2, and CF3 of the color filter layer CFL.

The overcoat layer OC may be located on the color filter layer CFL.

The window WD may be located on the overcoat layer OC.

The pixel PX may include a first pixel PX1, a second pixel PX2, and a third pixel PX3 that provide lights of different colors (or wavelengths). For example, the first pixel PX1 may provide red light, the second pixel PX2 may provide green light, and the third pixel PX3 may provide blue light.

The pixel transistors TR1 to TR3, the pixel electrode PE, the intermediate electrode ME, the light emitting layer LEML, and the color filter layer CFL described above may be provided for each pixel.

For example, the pixel electrode PE may include a first pixel electrode PE1 of the first pixel PX1, a second pixel electrode PE2 of the second pixel PX2, and a third pixel electrode PE3 of the third pixel PX3.

The intermediate electrode ME may include a first intermediate electrode ME1 of the first pixel PX1, a second intermediate electrode ME2 of the second pixel PX2, and a third intermediate electrode ME3 of the third pixel PX3.

The light emitting layer LEML may include a first light emitting layer LEML1 of the first pixel PX1, a second light emitting layer LEML2 of the second pixel PX2, and a third light emitting layer LEML3 of the third pixel PX3. Here, the first light emitting layer LEML1, the second light emitting layer LEML2, and the third light emitting layer LEML3 may provide lights of different colors (or wavelengths). For example, when the first pixel PX1, the second pixel PX2, and the third pixel PX3 provide the red light, the green light, and the blue light, respectively, as described above, the first light emitting layer LEML1 may include an organic light emitting layer providing the red light, the second light emitting layer LEML2 may include an organic light emitting layer providing the green light, and the third light emitting layer LEML3 may include an organic light emitting layer providing the blue light.

The color filter layer CFL may include a first color filter CF1 of the first pixel PX1, a second color filter CF2 of the second pixel PX2, and a third color filter CF3 of the third pixel PX3. Here, the first color filter CF1, the second color filter CF2, and the third color filter CF3 may selectively transmit lights of different colors (or wavelengths). For example, when the first pixel PX1, the second pixel PX2, and the third pixel PX3 provide the red light, the green light, and the blue light, respectively, as described above, the first color filter CF1 may selectively transmit the red light, the second color filter CF2 may selectively transmit the green light, and the third color filter CF3 may selectively transmit the blue light.

The pixel transistor may include a first pixel transistor TR1, a second pixel transistor TR2, and a third pixel transistor TR3. Here, the first pixel transistor TR1 may be any one of the first to eighth transistors T1 to T8 of FIG. 5. For example, the first pixel transistor TR1 may be the sixth transistor T6 of the first pixel PX1, the second pixel transistor TR2 may be the sixth transistor T6 of the second pixel PX2, and the third pixel transistor TR3 may be the sixth transistor T6 of the third pixel PX3.

An insulating layer INS may be located between the substrate SUB and the pixel electrode PE. The pixel electrode PE described above may be located on the insulating layer INS. The first pixel electrode PE1 may be connected to the first pixel transistor TR1, the second pixel electrode PE2 may be connected to the second pixel transistor TR2, and the third pixel electrode PE3 may be connected to the third pixel transistor TR3.

According to some embodiments, the light emitting element ED and the photovoltaic element OPV are arranged in a vertical direction (e.g., the third direction DR3) so as to overlap each other, and thus, an area of the pixel PX in a horizontal direction (e.g., the first direction DR1 and the second direction DR2) may be relatively reduced. Accordingly, the number of pixels arranged per unit area of the display area DA may be increased. Accordingly, a resolution of the display device 10 may be relatively improved.

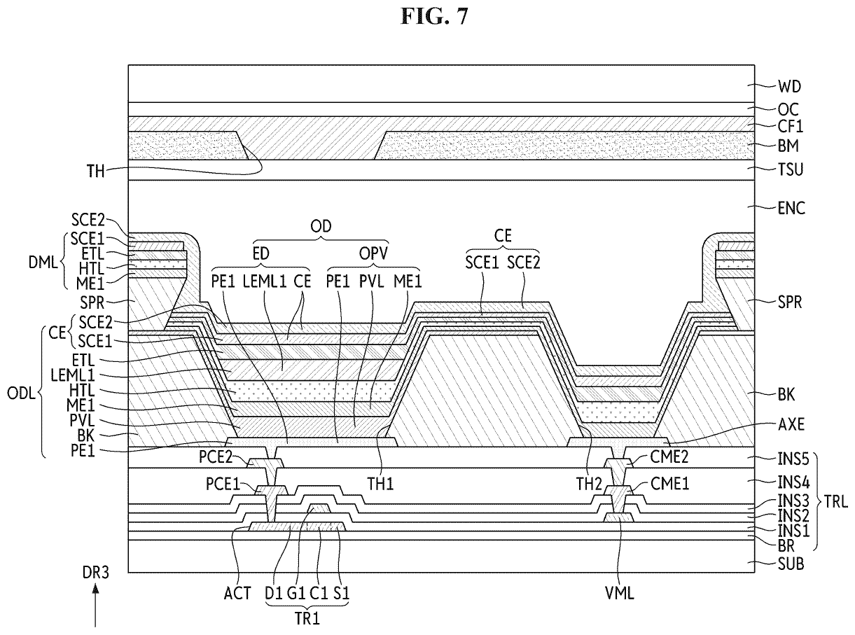

FIG. 7 is a detailed cross-sectional view of the display device 10 according to some embodiments. For example, FIG. 7 may be a detailed cross-sectional view of the display device 10 including the first pixel PX1 of FIG. 6.

The display device 10 according to some embodiments may include a substrate SUB, a transistor layer TRL, an optical element layer ODL, an encapsulation layer ENC, a touch sensing unit TSU, a light blocking layer BM, a first color filter CF1, an overcoat layer OC, and a window WD, as illustrated in FIG. 7.

The transistor layer TRL may include a barrier layer BR, an active layer ACT, a first insulating layer INS1, an intermediate voltage line VML, a second insulating layer INS2, a third insulating layer INS3, a first pixel connection electrode PCE1, a first intermediate connection electrode CME1, a fourth insulating layer INS4, a second pixel connection electrode PCE2, a second intermediate connection electrode CME2, and a fifth insulating layer INS5.

The optical element layer ODL may include a light emitting element ED, a photovoltaic element OPV, an auxiliary connection electrode AXE, a bank BK, a hole transporting layer HTL, an electron transporting layer ETL, a common electrode CE, and a separator SPR. The light emitting element ED may include a first pixel electrode PE1, a first light emitting layer LEML1, and a common electrode CE. The photovoltaic element OPV may include a first pixel electrode PE1, a photovoltaic layer PVL, and a first intermediate electrode ME1. The common electrode CE may include a first sub-common electrode SCE1 and a second sub-common electrode SCE2.

The barrier layer BR may be located on the substrate SUB. The barrier layer BR may include an inorganic insulating material including silicon nitride, silicon oxide, silicon oxynitride, or the like, or other insulating materials.

The active layer ACT may be located on the barrier layer BR. The active layer ACT may include a drain electrode D1, a channel region C1, and a source electrode S1. The active layer ACT may include polycrystalline silicon, single crystal silicon, low-temperature polycrystalline silicon, amorphous silicon, an oxide semiconductor, or other semiconductor materials.

The first insulating layer INS1 may be located on the active layer ACT. The first insulating layer INS1 may include at least one inorganic insulating layer including an inorganic insulating material.

A gate electrode G1 and the intermediate voltage line VML may be located on the first insulating layer INS1. For example, the gate electrode G1 may be located on the first insulating layer INS1 so as to overlap the channel region C1 of the active layer ACT. The gate electrode G1 may include any one of molybdenum (Mo), aluminum (Al), chromium (Cr), gold (Au), titanium (Ti), nickel (Ni), neodymium (Nd), and copper (Cu), or alloys thereof. The intermediate voltage line VML may be made of the same material as the gate electrode G1. The first pixel transistor TR1 may include the gate electrode G1, the source electrode S1, and the drain electrode D1.

The second insulating layer INS2 may be located on the gate electrode G1 and the intermediate voltage line VML. The second insulating layer INS2 may include at least one inorganic insulating layer including an inorganic insulating material.

The third insulating layer INS3 may be located on the second insulating layer INS2. The third insulating layer INS3 may include at least one inorganic insulating layer including an inorganic insulating material.

The first pixel connection electrode PCE1 and the first intermediate connection electrode CME1 may be located on the third insulating layer INS3. The first pixel connection electrode PCE1 may be connected to the drain electrode D1 of the first pixel transistor TR1 through a contact hole penetrating through the third insulating layer INS3 and the second insulating layer INS2. The first intermediate connection electrode CME1 may be connected to an intermediate voltage line VML through a contact hole penetrating through the third insulating layer INS3 and the second insulating layer INS2. The first pixel connection electrode PCE1 may include any one of molybdenum (Mo), aluminum (Al), chromium (Cr), gold (Au), titanium (Ti), nickel (Ni), neodymium (Nd), and copper (Cu), or alloys thereof. The first intermediate connection electrode CME1 may be made of the same material as the first pixel connection electrode PCE1.

The fourth insulating layer INS4 may be located on the first pixel connection electrode PCE1 and the first intermediate connection electrode CME1. The fourth insulating film INS4 may include at least one organic insulating layer including an acrylic resin, an epoxy resin, a phenolic resin, a polyamide resin, a polyimide resin, or other organic insulating materials.

The second pixel connection electrode PCE2 and the second intermediate connection electrode CME2 may be located on the fourth insulating layer INS4. The second pixel connection electrode PCE2 may be connected to the first pixel connection electrode PCE1 through a contact hole penetrating through the fourth insulating layer INS4. The second intermediate connection electrode CME2 may be connected to the first intermediate connection electrode CME1 through a contact hole penetrating through the fourth insulating layer INS4.

The fifth insulating layer INS5 may be located on the second pixel connection electrode PCE2 and the second intermediate connection electrode CME2. The fifth insulating layer INS5 may be made of the same material as the fourth insulating layer INS4.

The first pixel electrode PE1 and the auxiliary connection electrode AXE may be located on the fifth insulating layer INS5.

The bank BK may be located on the first pixel electrode PE1 and the auxiliary connection electrode AXE. The bank BK may have a first through hole TH1 and a second through hole TH2 penetrating through the bank BK in the third direction DR3. The first through hole TH1 of the bank BK may overlap the first pixel electrode PE1, and the second through hole TH2 of the bank BK may overlap the auxiliary connection electrode AXE. A portion of the first pixel electrode PE1 may be exposed through the first through hole TH1, and a portion of the auxiliary connection electrode AXE may be exposed through the second through hole TH2. The bank BK may overlap an edge of the first pixel electrode PE1 and an edge of the auxiliary connection electrode AXE.

The photovoltaic layer PVL may be located on the bank BK and the first pixel electrode PE1. For example, the photovoltaic layer PVL may be located on the bank BK and the first pixel electrode PE1, and in this case, the photovoltaic layer PVL may be located on the first pixel electrode PE1 through the first through hole TH1 of the bank BK. The photovoltaic layer PVL may also be located on inner walls of the first through hole TH1. For example, the photovoltaic layer PVL may be located on all portions of the bank BK excluding inner walls of the second through hole TH2.

The separator SPR may be located on the photovoltaic layer PVL. For example, the separator SPR may be located on the photovoltaic layer PVL so as to overlap the bank BK (e.g., an upper surface of the bank BK). In other words, the separator SPR may be located on the photovoltaic layer PVL so as not to cover (or so as not to overlap) the first through hole TH1 and the second through hole TH2 of the bank BK. The separator SPR may have a width that gradually decreases in a direction toward the bank BK (e.g., in a direction opposite to the third direction DR3). Accordingly, an angle (e.g., a taper angle) formed by a side surface and a lower surface of the separator SPR may be an obtuse angle. Here, the lower surface of the separator SPR may be an interface with the photovoltaic layer PVL, and the side surface of the separator SPR may be a surface neighboring to the lower surface of the separator SPR. The separator SPR may be located between pixels neighboring to each other. In a plan view, the separator SPR may surround (e.g., entirely surround) (e.g., in a periphery or outside a footprint of) the first through hole TH1 and the second through hole TH2. An example in which the first through hole TH1 and the second through hole TH2 located in the first pixel PX1 are surrounded (e.g., entirely surrounded by) by the separator SPR has been illustrated in FIG. 7.

The first intermediate electrode ME1 may be located on the separator SPR, the photovoltaic layer PVL, and the auxiliary connection electrode AXE. The first intermediate electrode ME1 may be located on the auxiliary connection electrode AXE within the second through hole TH2 of the bank BK. The first intermediate electrode ME1 may also be located on the inner walls of the second through hole TH2. The taper angle of the separator SPR is the obtuse angle, and accordingly, the first intermediate electrode ME1 may be cut on the separator SPR. Accordingly, the first intermediate electrode ME1 located on the separator SPR may be separated from the first intermediate electrode ME1 located on the photovoltaic layer PVL and the auxiliary connection electrode AXE.

The hole transporting layer HTL may be located on the first intermediate electrode ME1. The taper angle of the separator SPR is the obtuse angle, and accordingly, the hole transporting layer HTL may be cut on the separator SPR. For example, the hole transporting layer HTL located on the first intermediate electrode ME1 so as to overlap the separator SPR and the hole transporting layer HTL located lower than an upper surface of the separator SPR may be separated from each other.

The first light emitting layer LEML1 may be located on the hole transporting layer HTL. For example, the first light emitting layer LEML1 may be located on the hole transporting layer HTL within the first through hole TH1 of the bank BK.

The electron transporting layer ETL may be located on the first light emitting layer LEML1 and the hole transporting layer HTL. The taper angle of the separator SPR is the obtuse angle, and accordingly, the electron transporting layer ETL may be cut on the separator SPR. For example, the electron transporting layer ETL located on the hole transporting layer HTL so as to overlap the separator SPR and the electron transporting layer ETL located lower than the upper surface of the separator SPR may be separated from each other.

The common electrode CE may be located on the electron transporting layer ETL. The common electrode CE may include a first sub-common electrode SCE1 and a second sub-common electrode SCE2 that are located on different layers. The first sub-common electrode SCE1 may be located on the electron transporting layer ETL. The taper angle of the separator SPR is the obtuse angle, and accordingly, the first sub-common electrode SCE1 may be cut on the separator SPR. For example, the first sub-common electrode SCE1 located on the electron transporting layer ETL so as to overlap the separator SPR and the first sub-common electrode SCE1 located lower than the upper surface of the separator SPR may be separated from each other. The second sub-common electrode SCE2 may be located on the first sub-common electrode SCE1. Because the side surface of the separator SPR is covered by stacked layers (e.g., the photovoltaic layer PVL, the first intermediate electrode ME1, the hole transporting layer HTL, the electron transporting layer ETL, and the first sub-common electrode SCE1) located between the upper surface of the bank BK and the second sub-common electrode SCE2, the second sub-common electrode SCE2 located on the first sub-common electrode SCE1 may not be cut. Accordingly, cut portions of the first sub-common electrode SCE1 may be connected to each other by the second sub-common electrode SCE2. In this way, a cut portion of the first intermediate electrode ME1, a cut portion of the hole transporting layer HTL, a cut portion of the electron transporting layer ETL, and a cut portion of the first sub-common electrode SCE1 may be arranged as a dummy layer DML on the separator SPR.

The encapsulation layer ENC may be located on the common electrode CE. For example, the encapsulation layer ENC may be located on the second sub-common electrode SCE2. The encapsulation layer ENC may include an inorganic layer, an organic layer, and an inorganic layer that are sequentially stacked.

The touch sensing unit TSU may be located on the encapsulation layer ENC.

The light blocking layer BM may be located on the touch sensing unit TSU. The light blocking layer BM may have a through hole TH overlapping the first through hole TH1 of the bank BK. The through hole TH of the light blocking layer BM may be smaller than the first through hole TH1 of the bank BK. For example, in a plan view, the through hole TH of the light blocking layer BM may be surrounded (e.g., entirely surrounded) by the first through hole TH1 of the bank BK.

The first color filter CF1 may be located on the light blocking layer BM. The first color filter CF1 may be located on an upper surface of the light blocking layer BM and in the through hole TH of the light blocking layer BM.

The overcoat layer OC may be located on the first color filter CF1. The overcoat layer OC may be a capping layer protecting the second and third color filters CF2 and CF3 as well as the first color filter CF1. The overcoat layer OC may include an inorganic layer. For example, the overcoat layer OC may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and the like.

The window WD may be located on the overcoat layer OC. The window WD may be located above the display panel 100 to protect the display panel 100. For example, the window WD may be provided on a display surface of the display panel 100.

The display device 10 including the second pixel PX2 and the third pixel PX3 may have a cross section as illustrated in FIG. 7. However, the second pixel PX2 may include a second light emitting layer LEML2 and a second color filter CF2 instead of the first light emitting layer LEML1 and the first color filter CF1, and the third pixel PX3 may include a third light emitting layer LEML3 and a third color filter CF3 instead of the first light emitting layer LEML1 and the first color filter CF1.

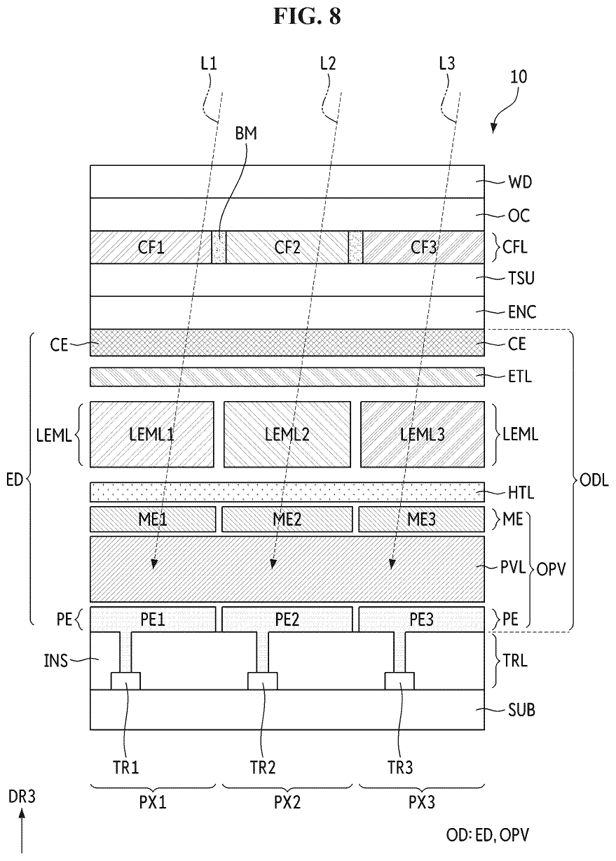

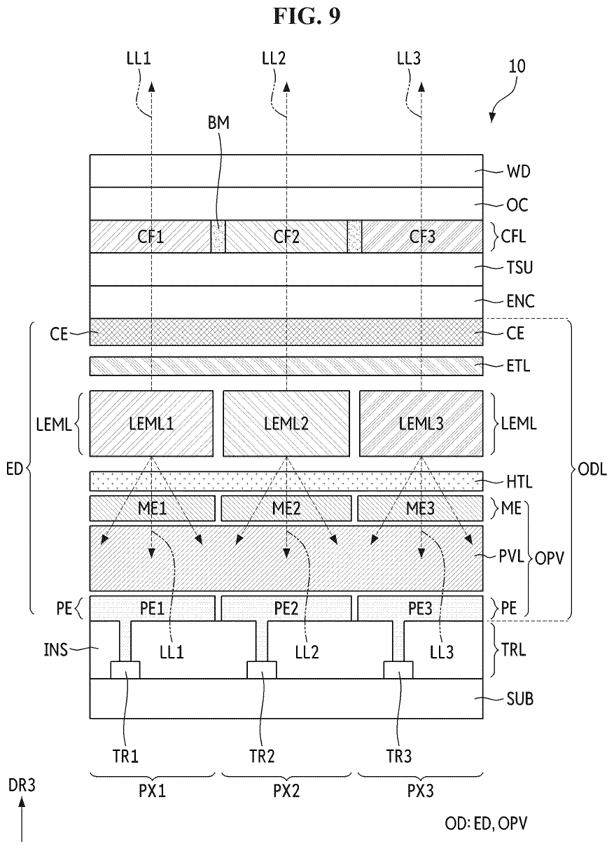

FIGS. 8 and 9 are views for describing a charging operation of the display device 10 of FIG. 6.

When the display device 10 (e.g., the pixel PX of the display device 10) operates in the charging mode, the photovoltaic element OPV may be switched to a state (hereinafter referred to as a drivable state) in which it may generate electric energy as described above.

As illustrated in FIG. 8, external lights L1, L2, and L3 may pass through the window WD and be incident on the photovoltaic element OPV. For example, the external lights L1, L2, and L3 may be incident on the photovoltaic layer PVL of the photovoltaic element OPV. For example, a first light L1 of the external lights may be incident on the photovoltaic layer PVL through the first color filter CF1, a second light L2 of the external lights may be incident on the photovoltaic layer PVL through the second color filter CF2, and a third light L3 of the external lights may be incident on the photovoltaic layer PVL through the third color filter CF3. In this case, the photovoltaic layer PVL may be activated by the incident lights L1, L2, and L3, and the activated photovoltaic layer PVL may generate electric energy. Here, the first light L1 passing through the first color filter CF1 may be red light (or light of a red wavelength band), the second light L2 passing through the second color filter CF2 may be green light (or light of a green wavelength band), and the third light L3 passing through the third color filter CF3 may be blue light (or light of a blue wavelength band).

As illustrated in FIG. 9, lights emitted from the light emitting element ED may not only be emitted to the outside of the display device 10 but may also be incident on the photovoltaic element OPV. For example, a first light LL1 from the first light emitting layer LEML1 of the first pixel PX1, a second light LL2 from the second light emitting layer LEML2 of the second pixel PX2, and a third light LL3 from the third light emitting layer LEML3 of the third pixel PX3 may not only be emitted to the outside of the display device 10 but may also be incident on the photovoltaic layer PVL of the photovoltaic element OPV. In this case, the photovoltaic layer PVL may be activated by the incident lights LL1, LL2, and LL3, and the activated photovoltaic layer PVL may generate electric energy.

According to some embodiments, the electric energy may be generated from the photovoltaic element OPV through the external light and the light from the light emitting element ED. Accordingly, a retention time of the battery 555 and a driving time and power consumption of the display device 10 may be relatively improved.

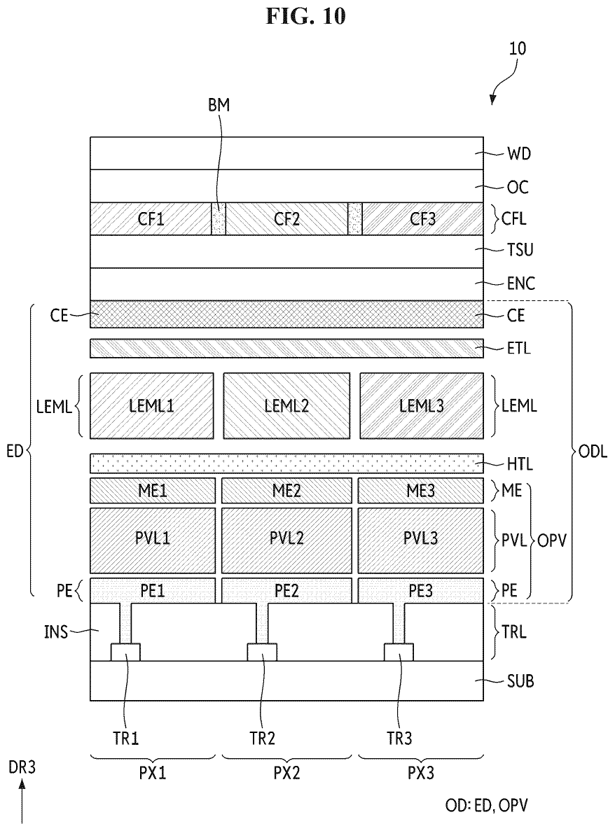

FIG. 10 is a schematic view of a display device 10 according to some embodiments.

The display device 10 of FIG. 10 is different from the display device 10 described above with reference to FIG. 6 in that it includes a plurality of photovoltaic layers PVL separated for each pixel, and such a difference will be mainly described below.

As illustrated in FIG. 10, the photovoltaic layer PVL may be provided for each pixel. For example, the photovoltaic layer PVL may include a first photovoltaic layer PVL1 of the first pixel PX1, a second photovoltaic layer PVL2 of the second pixel PX2, and the third photovoltaic layer PVL3 of the third pixel PX3.

The photovoltaic layers PVL1, PVL2, and PVL3 may more effectively absorb lights of different colors (or wavelengths). For example, the first photovoltaic layer PVL1 may more effectively absorb a first light, which is a red light, of first to third lights, the second photovoltaic layer PVL2 may more effectively absorb a second light, which is a green light, of the first to third lights, and the third photovoltaic layer PVL3 may more effectively absorb a third light, which is a blue light, of the first to third lights.

The first photovoltaic layer PVL1 may be located between the first pixel electrode PE1 and the first intermediate electrode ME1 so as to overlap the first light emitting layer LEML1 (and/or the first color filter CF1).

The second photovoltaic layer PVL2 may be located between the second pixel electrode PE2 and the second intermediate electrode ME2 so as to overlap the second light emitting layer LEML2 (and/or the second color filter CF2).

The third photovoltaic layer PVL3 may be located between the third pixel electrode PE3 and the third intermediate electrode ME3 so as to overlap the third light emitting layer LEML3 (and/or the third color filter CF3).

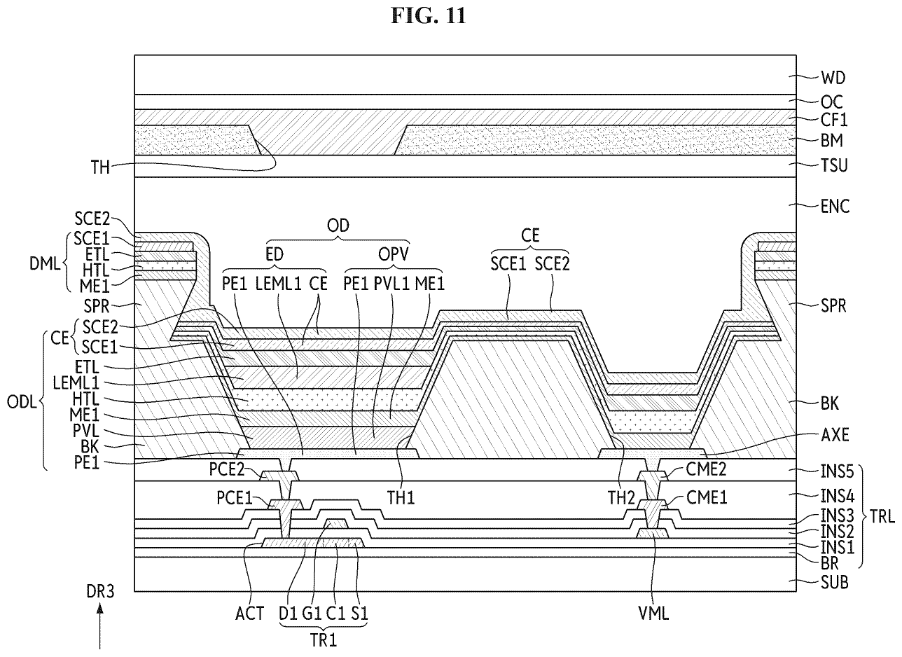

FIG. 11 is a detailed cross-sectional view of the display device 10 according to some embodiments. For example, FIG. 11 may be a detailed cross-sectional view of the display device 10 including the first pixel PX1 of FIG. 10.

The display device 10 of FIG. 11 is different from the display device 10 described above with reference to FIG. 7 in that each photovoltaic layer PVL is located only in the first through hole TH1 of the bank BK, and such a difference will be mainly described below.

As illustrated in FIG. 11, the first photovoltaic layer PVL1 may be located on the first pixel electrode PE1 within the first through hole TH1 of the bank BK. For example, the first photovoltaic layer PVL1 may be located between the first pixel electrode PE1 and the first intermediate electrode ME1 within the first through hole TH1.

In addition, as illustrated in FIG. 11, the separator SPR may be located on an upper surface of the bank BK. For example, the bank BK and the separator SPR may be in contact (or in direct contact) with each other.

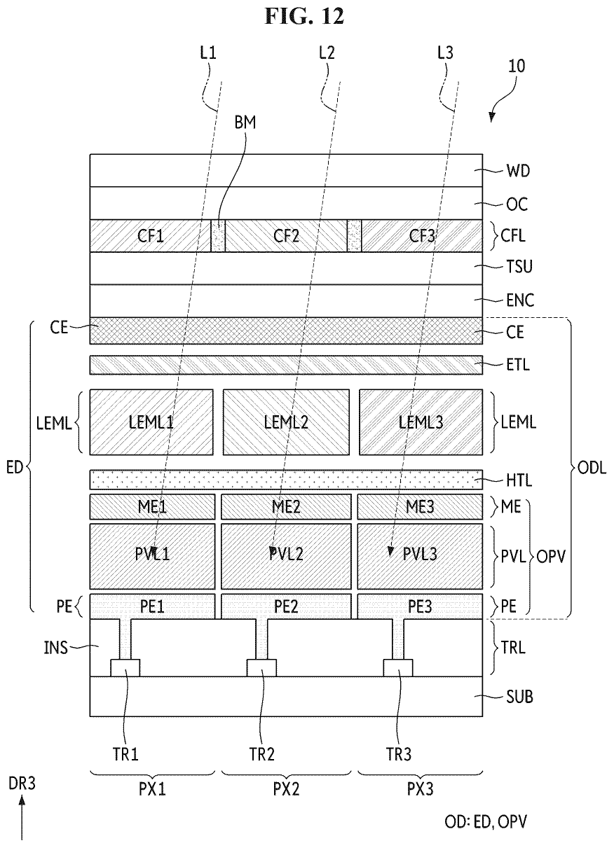

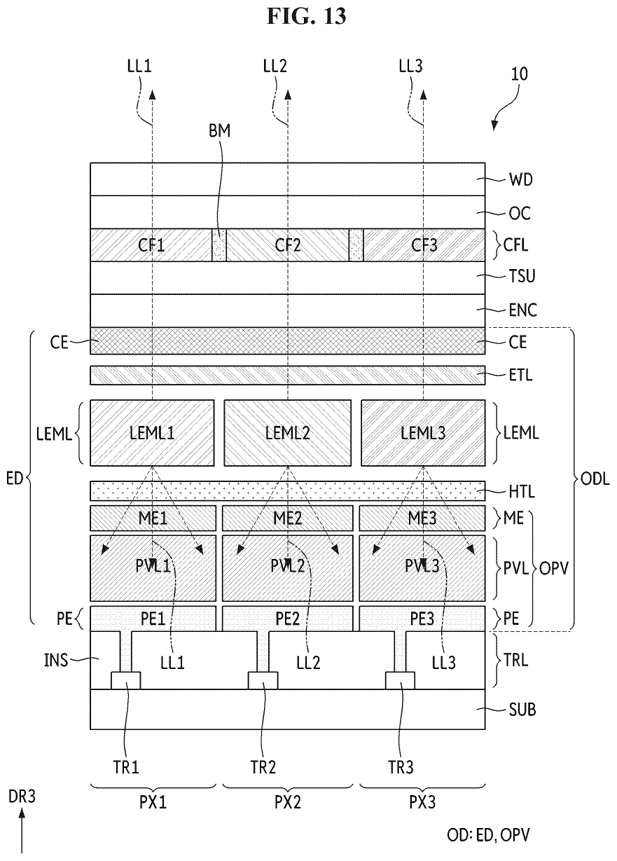

FIGS. 12 and 13 are views for describing a charging operation of the display device 10 of FIG. 10.

When the display device 10 (e.g., the pixel of the display device 10) operates in the charging mode, the photovoltaic element OPV may be switched to a state (hereinafter referred to as a drivable state) in which it may generate electric energy as described above.

As illustrated in FIG. 12, external lights L1, L2, and L3 may pass through the window WD and be incident on the photovoltaic element OPV. For example, the external lights L1, L2, and L3 may be incident on the first to third photovoltaic layers PVL1, PVL2, and PVL3 of the photovoltaic element OPV. For example, a first light L1 of the external lights L1, L2, and L3 may be incident on the first photovoltaic layer PVL1 through the first color filter CF1, a second light L2 of the external lights L1, L2, and L3 may be incident on the second photovoltaic layer PVL2 through the second color filter CF2, and a third light L3 of the external lights L1, L2, and L3 may be incident on the third photovoltaic layer PVL3 through the third color filter CF3. In this case, the first to third photovoltaic layers PVL1, PVL2, and PVL3 may be activated by the incident lights L1, L2, and L3, respectively, and each of the activated first to third photovoltaic layers PVL1, PVL2, and PVL3 may generate electric energy. Here, the first light L1 passing through the first color filter CF1 may be red light (or light of a red wavelength band), the second light L2 passing through the second color filter CF2 may be green light (or light of a green wavelength band), and the third light L3 passing through the third color filter CF3 may be blue light (or light of a blue wavelength band).

As illustrated in FIG. 13, lights LL1, LL2, and LL3 emitted from the light emitting element ED may not only be emitted to the outside of the display device 10 but may also be incident on the photovoltaic element OPV. For example, a first light LL1 from the first light emitting layer LEML1 of the first pixel PX1, a second light LL2 from the second light emitting layer LEML2 of the second pixel PX2, and a third light LL3 from the third light emitting layer LEML3 of the third pixel PX3 may not only be emitted to the outside of the display device 10 but may also be incident on the first to third photovoltaic layers PVL1, PVL2, and PVL3 of the photovoltaic element OPV. For example, the first light LL1 from the first light emitting layer LEML1 may be incident on the first photovoltaic layer PVL1, the second light LL2 from the second light emitting layer LEML2 may be incident on the second photovoltaic layer PVL2, and the third light LL3 from the third light emitting layer LEML3 may be incident on the third photovoltaic layer PVL3. In this case, the first to third photovoltaic layers PVL1, PVL2, and PVL3 may be activated by the incident lights LL1, LL2, and LL3, respectively, and each of the activated first to third photovoltaic layers PVL1, PVL2, and PVL3 may generate electric energy.

The display device 10 according to some embodiments may be applied to various electronic devices. An electronic device according to some embodiments includes the display device 10 described above, and may further include modules or devices having other additional functions in addition to the display device 10.

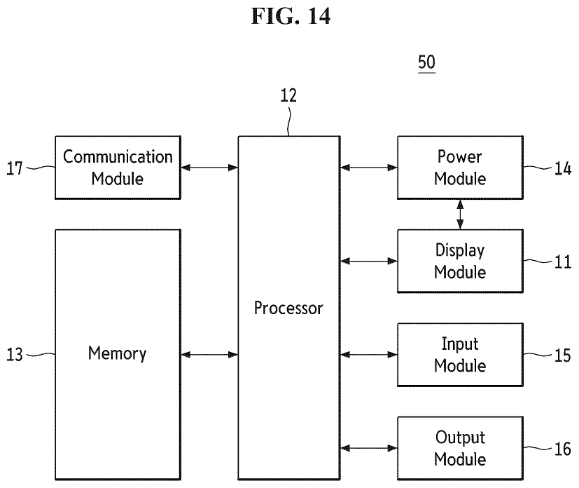

FIG. 14 is a block diagram of an electronic device according to some embodiments. Referring to FIG. 14, an electronic device 50 according to some embodiments may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to a user through the display module 11. The power module 14 may include a power supply module such as a power adapter or a battery device and a power conversion module converting power supplied by the power supply module to generate power necessary for an operation of the electronic device 50. The input module 15 may provide input information to the processor 12 and/or the display module 11. The non-image output module 16 may serve to receive information other than an image received from the processor 12, such as sound information, haptic information, and light emitting information, and provide the received information to the user. The communication module 17 is a module in charge of transmitting and receiving information between the electronic device 50 and an external device, and may include a receiving unit and a transmitting unit.

At least one of the respective components of the above-described electronic device 50 may be included in the display device according to the above-described embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 10 rather than the display device.

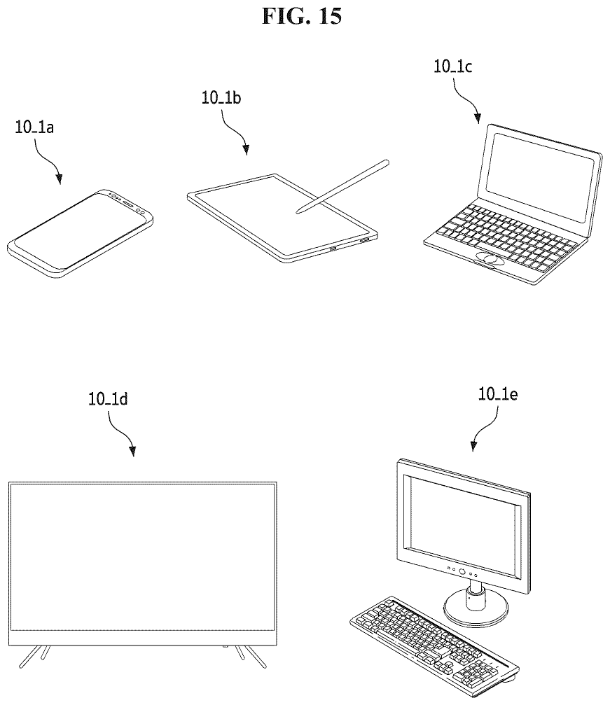

FIGS. 15 to 17 are schematic views of electronic devices according to various embodiments. FIGS. 15 to 17 illustrate examples of various electronic devices to which the display device 10 according to embodiments is applied.

FIG. 15 illustrates a smartphone 10_1a, a tablet PC 10_1b, a laptop computer 10_1c, a television (TV) 10_1d, and a monitor 10_1e for a desktop computer as examples of the electronic devices.

The smartphone 10_1a may include an input module such as a touch sensor and a communication module in addition to the display module 11. The smartphone 10_1a may process information received through the communication module or other input modules and display the processed information through the display module of the display device.

Each of the tablet PC 10_1b, the laptop computer 10_1c, the TV 10_1d, and the monitor 10_1e for a desktop computer may include a display module and an input module, similar to the smartphone 10_1a, and may further include a communication module in some cases.

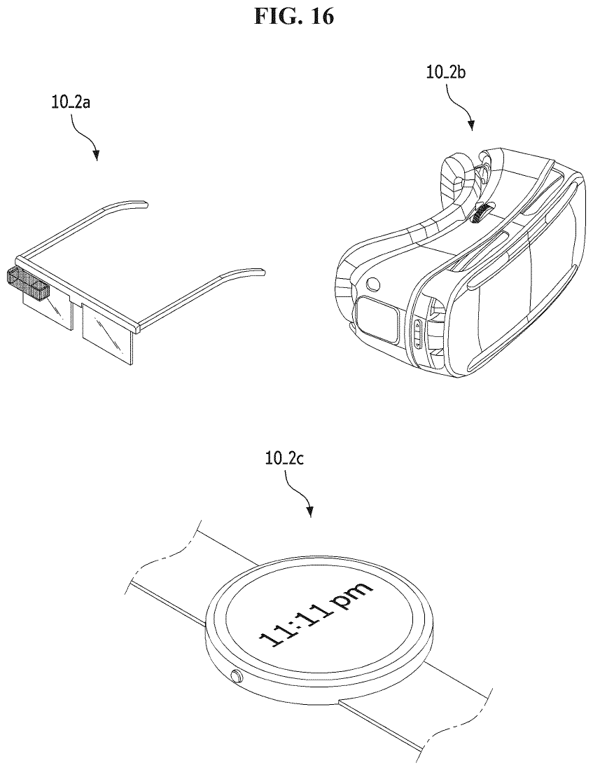

FIG. 16 illustrates a case where an electronic device including a display module is applied to a wearable electronic device. The wearable electronic device may be a smart glasses 10_2a, a head mounted display 10_2b, a smart watch 10_2c, or the like.

The smart glasses 10_2a and the head mounted display 10_2b may include a display module emitting a display image and a reflector reflecting the emitted display image and providing the emitted display image to user's eyes, and accordingly, may provide a virtual reality screen or an augmented reality screen to the user.

The smart watch 10_2c may include a biometric sensor as an input device, and may provide biometric information recognized through the biometric sensor to the user through the display module.

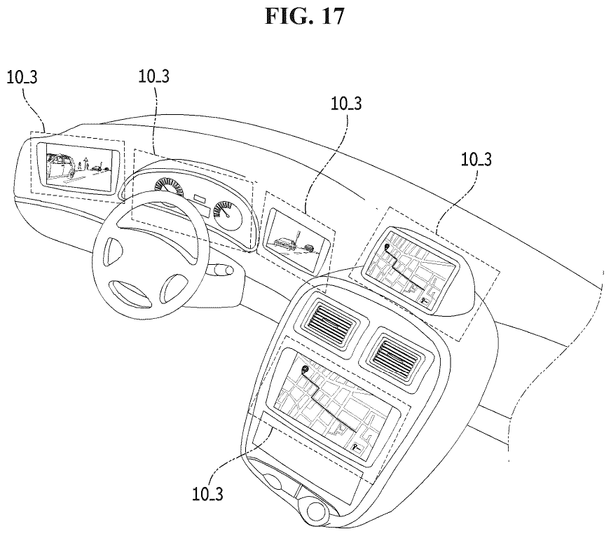

FIG. 17 illustrates a case where an electronic device including a display module is applied to a vehicle. For example, an electronic device 10_3 may be applied to an instrument board, a center fascia, or the like, of the vehicle or applied to a center information display (CID) located on a dashboard of the vehicle, a room mirror display substituting for a side-view mirror, or the like.

In concluding the detailed description, those skilled in the art will appreciate that many variations and modifications can be made to the disclosed embodiments without substantially departing from the spirit and scope of embodiments according to the present disclosure, as defined in the appended claims, and their equivalents. Therefore, the disclosed embodiments of the invention are used in a generic and descriptive sense only and not for purposes of limitation.

What is claimed is:

1. A display device comprising:
a substrate;
a transistor layer on the substrate; and
an optical element layer on the transistor layer,
wherein the optical element layer includes:
a pixel electrode on the transistor layer;
a bank on the pixel electrode and having a first through hole overlapping a portion of the pixel electrode;
a photovoltaic layer on the pixel electrode;
an intermediate electrode on the photovoltaic layer;
a light emitting layer on the intermediate electrode; and
a common electrode on the light emitting layer.

2. The display device of claim 1, wherein the optical element layer includes a light emitting element and a photovoltaic element,
the light emitting element includes the pixel electrode, the light emitting layer, and the common electrode; and
the photovoltaic element includes the pixel electrode, the photovoltaic layer, and the intermediate electrode.

3. The display device of claim 1, further comprising an auxiliary connection electrode on the transistor layer and connected to the intermediate electrode.

4. The display device of claim 3, wherein the bank is further on the auxiliary connection electrode, and
the bank further has a second through hole overlapping a portion of the auxiliary connection electrode.

5. The display device of claim 4, wherein the intermediate electrode is on the auxiliary connection electrode within the second through hole.

6. The display device of claim 1, wherein the photovoltaic layer is further on an upper surface of the bank.

7. The display device of claim 6, further comprising a separator on the photovoltaic layer so as to overlap the bank.

8. The display device of claim 1, further comprising:
a separator on the bank; and
a dummy layer on the separator.

9. The display device of claim 8, wherein the dummy layer includes:
a cut portion of the intermediate electrode separated from the intermediate electrode; and
a cut portion of the common electrode separated from the common electrode.

10. The display device of claim 9, wherein the common electrode includes:
a first sub-common electrode on the light emitting layer and the separator; and
a second sub-common electrode on the first sub-common electrode.

11. The display device of claim 10, wherein the cut portion of the common electrode is separated from the first sub-common electrode.

12. The display device of claim 1, wherein the transistor layer includes a pixel circuit including a plurality of transistors and at least one capacitor, and
at least one of the plurality of transistors is connected to the pixel electrode.

13. The display device of claim 12, further comprising:
a driving voltage line connected to the pixel circuit and configured to transmit a driving voltage, and a common voltage line connected to the pixel circuit and configured to transmit a common voltage; and
an intermediate voltage line connected to an optical element of the optical element layer and configured to transmit an intermediate voltage.

14. The display device of claim 13, wherein the driving voltage has a smaller value in a charging mode than in a light emitting mode.

15. The display device of claim 14, wherein in the light emitting mode, the intermediate voltage is greater than the common voltage and smaller than the driving voltage.

16. The display device of claim 14, wherein in the charging mode, the driving voltage is greater than the common voltage and smaller than the intermediate voltage.

17. An electronic device comprising a display device providing a screen,
wherein the display device includes:
a substrate;
a transistor layer on the substrate; and
an optical element layer on the transistor layer, and
the optical element layer includes:
a pixel electrode on the transistor layer;
a bank on the pixel electrode and having a first through hole overlapping a portion of the pixel electrode;
a photovoltaic layer on the pixel electrode;
an intermediate electrode on the photovoltaic layer;
a light emitting layer on the intermediate electrode; and
a common electrode on the light emitting layer.

18. The electronic device of claim 17, wherein the optical element layer includes a light emitting element and a photovoltaic element,
the light emitting element includes the pixel electrode, the light emitting layer, and the common electrode; and
the photovoltaic element includes the pixel electrode, the photovoltaic layer, and the intermediate electrode.

19. The electronic device of claim 17, wherein the display device further includes: an auxiliary connection electrode on the transistor layer and connected to the intermediate electrode; and
a battery connected to an optical element of the optical element layer,
wherein the bank is further on the auxiliary connection electrode, and
the bank further has a second through hole overlapping a portion of the auxiliary connection electrode.

20. The electronic device of claim 17, wherein the electronic device is one of a smartphone, a tablet personal computer (PC), a laptop computer, a television (TV), a monitor for a desktop computer, a smart glasses, a smart watch, a head mounted display, or a vehicle.
